(19) United States
(12) Patent Application Publication
(10) Pub. No.: US 2026/0075792 A1
(43) Pub. Date: Mar. 12, 2026

(54) METHOD FOR FORMING MEMORY DEVICE

(71) Applicant: NANYA TECHNOLOGY CORPORATION, New Taipei City (TW)

(72) Inventor: Hsu CHIANG, New Taipei City (TW)

(21) Appl. No.: 18/826,195

(22) Filed: Sep. 6, 2024

(51) Int. Cl. H10B 12/00

(52) U.S. Cl. CPC H10B 12/033; H10D 1/043; H10D 1/716

(57) ABSTRACT

A method includes forming a stack including a first sacrificial layer, a first supporting layer, a second sacrificial layer, and a second supporting layer over a substrate; forming first and second trenches; forming bottom electrodes in the first and second trenches; forming a patterned mask over the stack, in which the patterned mask has an opening exposing the stack; performing an etch process to the stack through the opening of the patterned mask, in which the etch process etches through a first portion of the stack to form a recess, while a second portion of the stack laterally between the first trench and the second trench is protected by a polymer generated during performing the etch process; removing the first and second sacrificial layers from the stack; forming capacitor dielectric layers over the bottom electrodes; and forming top electrodes over the capacitor dielectric layers.

### BACKGROUND

Semiconductor devices, such as memory devices, Dynamic Random Access Memory (DRAM) for storage of information, or others, are currently in widespread use, in a myriad of applications. The DRAM include a plurality of DRAM cells, each of which includes a capacitor for storing information and a transistor coupled to the capacitor for regulating the timing of when the capacitor is charged or discharged. During a read operation, a word line (WL) is asserted, turning on the transistor. The enabled transistor allows the voltage across the capacitor to be read by a sense amplifier through a bit line (BL). During a write operation, the data to be written is provided on the BL when the WL is asserted.

### SUMMARY

In some embodiments of the present disclosure, a method for forming a memory device includes forming a stack including a first sacrificial layer, a first supporting layer, a second sacrificial layer, and a second supporting layer over a substrate; forming a first trench and a second trench in the stack; forming bottom electrodes in the first trench and the second trench, respectively; forming a patterned mask over the stack, in which the patterned mask has an opening exposing the stack; performing an etch process to the stack through the opening of the patterned mask, in which the etch process etches through a first portion of the stack to form a recess, while a second portion of the stack laterally between the first trench and the second trench is protected by a polymer generated during performing the etch process; removing the first sacrificial layer and the second sacrificial layer from the stack through the recess; forming capacitor dielectric layers over the bottom electrodes, respectively; and forming top electrodes over the capacitor dielectric layers, respectively.

In some embodiments, the polymer is formed on surfaces of the bottom electrodes during performing the etching process.

In some embodiments, a portion of the second supporting layer of the second portion of the stack is etched during the etch process.

In some embodiments, the method further includes removing the patterned mask after removing the first sacrificial layer and the second sacrificial layer; and removing the polymer.

In some embodiments, the method further includes removing the polymer is performed after removing the patterned mask.

In some embodiments, the capacitor dielectric layers are formed over the second supporting layer and in the recess.

In some embodiments, the method further includes forming an insulating layer over the top electrodes and filling the recess.

In some embodiments, the method further includes forming a transistor in the substrate, wherein one of the bottom electrodes is electrically connected to the transistor.

In some embodiments, the polymer extends from a first portion of the bottom electrodes within the first trench to a second portion of the bottom electrodes within the second trench.

In some embodiments, the method further includes forming the first trench and the second trench in the stack further comprises forming a third trench in the stack, a shortest distance between the first trench and the second trench is less than a shortest distance between the first trench and the third trench, and in which the recess is formed laterally between the first trench and the third trench.

In some embodiments of the present disclosure, a method for forming a memory device includes forming a stack including a first sacrificial layer, a first supporting layer, a second sacrificial layer, and a second supporting layer over a substrate; forming a first trench, a second trench, and a third trench in the stack, in which a distance between the first trench and the second trench is less than a distance between the first trench and the third trench; forming bottom electrodes in the first, second, and third trenches, respectively; forming a patterned mask over the stack, in which the patterned mask has an opening exposing the stack; performing an etch process to the stack through the opening of the patterned mask to form a recess in the stack, in which after the etch process is complete, a first portion of the second supporting layer laterally between the first trench and the second trench remains, while a second portion of the second supporting layer laterally between the first trench and the third trench is removed; removing the first sacrificial layer and the second sacrificial layer from the stack through the recess; forming capacitor dielectric layers over the bottom electrodes, respectively; and forming top electrodes over the capacitor dielectric layers, respectively.

In some embodiments, the method further includes performing the etch process further includes forming a polymer over the first portion of the second supporting layer.

In some embodiments, the polymer further extend to portions of the bottom electrodes within the first trench and the second trench.

In some embodiments, the polymer wraps top ends of the bottom electrodes within the first trench and the second trench.

In some embodiments, the method further includes removing the patterned mask after removing the first sacrificial layer and the second sacrificial layer; and removing the polymer after removing the patterned mask.

In some embodiments, the method further includes removing the polymer further comprises removing the first portion of the second supporting layer.

In some embodiments, after the etch process is complete, a top surface of the first portion of the second supporting layer is lower than top ends of the bottom electrodes.

In some embodiments, the etch process is performed such that a thickness of the first portion of the second supporting layer is reduced.

In some embodiments, the method further includes forming a transistor in the substrate, wherein one of the bottom electrodes is electrically connected to a source/drain region of the transistor.

In some embodiments, the etch process is performed such that portions of the first sacrificial layer, the first supporting layer, and the second sacrificial layer under the second portion of the second supporting layer are removed.

### BRIEF DESCRIPTION OF THE DRAWINGS

The invention can be more fully understood by reading the following detailed description of the embodiment, with reference made to the accompanying drawings as follows:

FIG. 1 is a circuit diagram of a memory cell of a memory device in accordance with some embodiments of the present disclosure.

FIGS. 2A to 10C illustrate a method in various stages of forming a memory device in accordance with some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

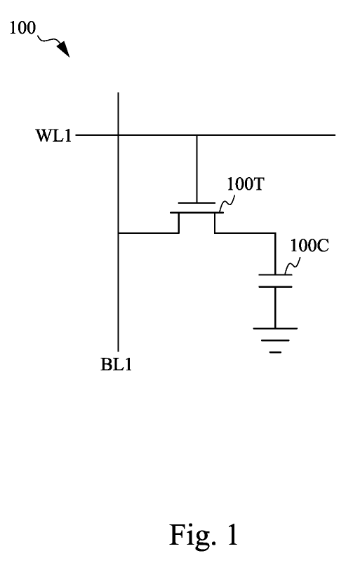

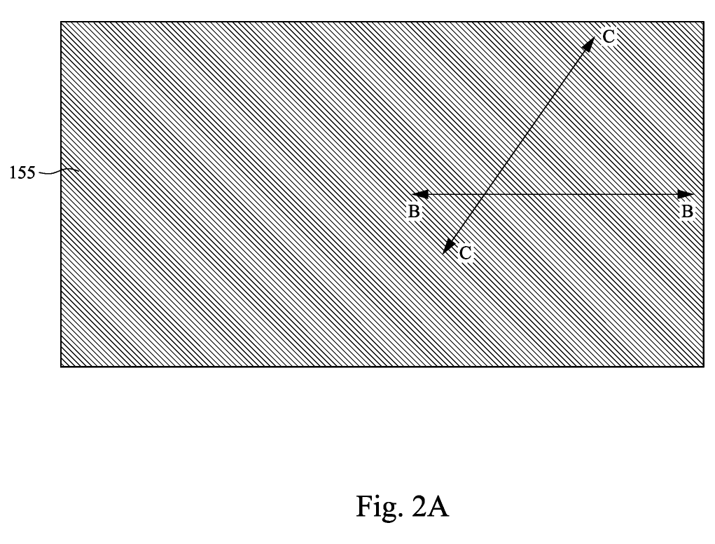

FIG. 1 is a circuit diagram of a memory cell of a memory device in accordance with some embodiments of the present disclosure. Shown there is a circuit diagram of a memory device 100. In some embodiments, the memory device 100 is a dynamic random access memory (DRAM) device. The memory device 100 includes a transistor 100T, a capacitor 100C, a word line WL1, and a bit line BL1. The transistor 100T is electrically connected to the word line WL1, and is also connected to the bit line BL1 that is arranged perpendicular to the word line WL1. The one side of the capacitor 100C is electrically connected to the transistor 100T, and the other side of the capacitor 100C is grounded. The operation of devices can be achieved by utilization of the word line WL1 and the bit line BL1, and the storage of data can be accomplished by controlling the charges in the capacitor 100C. The charge transportation over the capacitor 100C can be determined by the control of transistor 100T, which may be manipulated by the bit line BL1 and the word line WL1 to characterize the reading and writing of the signal.

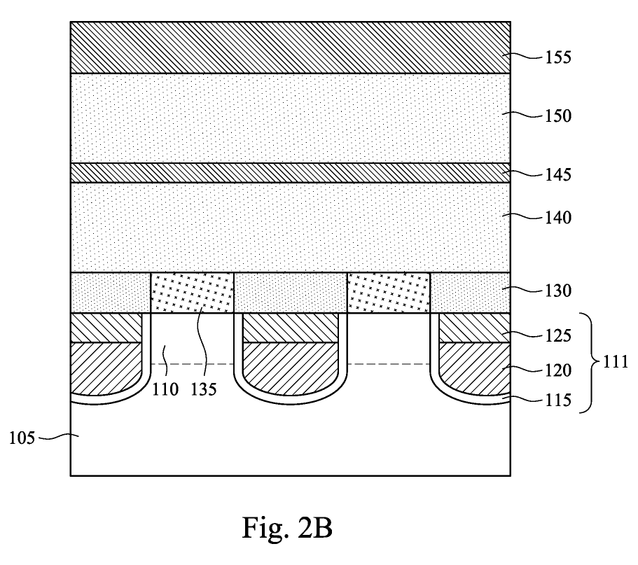

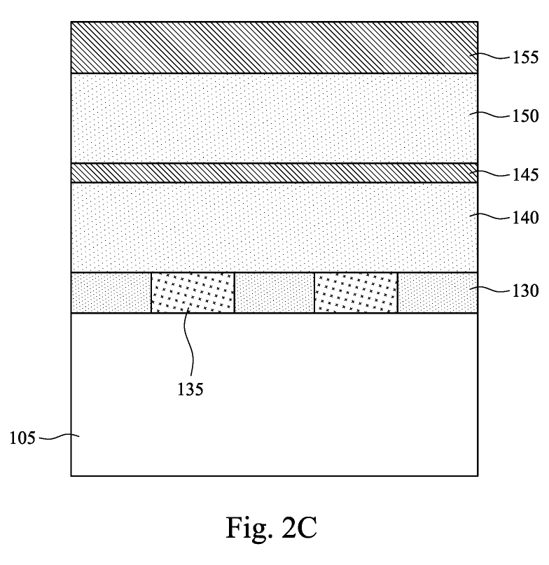

FIGS. 2A to 10C illustrate a method in various stages of forming a memory device in accordance with some embodiments of the present disclosure. In greater detail, FIGS. 2A to 10C illustrate a method for forming the memory device 100 as shown in FIG. 1. Although FIGS. 2A to 10C are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 2A to 2C, in which FIG. 2A is a top view of a memory device, and FIGS. 2B and 2C are cross-sectional views along the lines B-B and C-C of FIG. 2A, respectively.

Shown there is a substrate 105. In some embodiments, the substrate 105 can be suitable semiconductor material, such as silicon, silicon carbide, gallium arsenic, gallium phosphide, germanium, indium antimonide, indium phosphide, indium arsenide, or the like. The substrate 105 may also be doped with suitable dopants.

A plurality of gate structures 111 are formed in the substrate 105. In some embodiments, each of the gate structures 111 may include a gate dielectric 115, a gate electrode 120, and a gate cap 125. The substrate 105 may include doped regions 110 on opposite sides of each gate structure 111. In some embodiments, the gate structure 111, the doped regions 110, and portion of the substrate 105 along the surface of the gate structure 111 (e.g., channel region) may collectively form the transistor 100T of the memory device 100 as discussed in FIG. 1. In some embodiments, the doped regions 110 may act as source/drain regions of the transistor.

In some embodiments, the gate dielectric 115 may include oxide, such as silicon oxide. In some embodiments, the gate electrode 120 may include suitable conductive material, such as polysilicon, cobalt, nickel, titanium, titanium nitride, tungsten, tungsten nitride, the like, or the combination thereof. In some embodiments, the gate cap 125 may include dielectric material, such as silicon oxide, silicon nitride, the like, or combinations thereof. In some embodiments, the doped regions 110 may include opposite conductivity type than the substrate 105. For example, when the substrate 105 is a p-type substrate, the doped regions 110 may be n-type doped regions. Similarly, when the substrate 105 is an n-type substrate, the doped regions 110 may be p-type doped regions.

A dielectric layer 130 is formed over a top surface of the substrate 105. In some embodiments, the dielectric layer 130 may include silicon oxide (SiO₂), carbon-doped silicon oxide, silicon nitride (Si₃N₄), silicon oxynitride (N₂OSi₂), silicon nitride oxide (N₂OSi₂), flowable oxide (FOx), undoped silicate glass (USG), borosilicate glass (BSG), phosphosilicate glass (PSG), borophosphosilicate glass (BPSG), tetraethyl orthosilicate (TEOS), fluorosilicate glass (FSG), xerogel, aerogel, amorphous fluorinated carbon (a-CFx), parylene, benzocyclobutene (BCB), polyimide (PI), or a combination thereof. In some embodiments, the dielectric layer 130 may be disposed by, for example, atomic layer deposition (ALD), chemical vapor deposition (CVD), physical vapor deposition (PVD), or other suitable methods.

Contacts 135 are formed in the dielectric layer 130. In some embodiments, the contacts 135 may be formed electrically connected to the doped regions 110 of the substrate 105. In some embodiments, the contacts 135 may include doped polysilicon (poly-Si), titanium (Ti), titanium nitride (TiN), tantalum (Ta), tantalum nitride (TaN), tungsten (W), copper (Cu), aluminum (Al), or an alloy thereof. In some embodiments, the contacts 135 may be disposed by, for example, atomic layer deposition (ALD), chemical vapor deposition (CVD), physical vapor deposition (PVD), or other suitable methods.

A stack of first sacrificial layer 140, first supporting layer 145, second sacrificial layer 150, and second supporting layer 155 is formed over the dielectric layer 130. The first sacrificial layer 140 and the second sacrificial layer 150 may be made of a same material, such as silicon oxide. In some embodiments, the first supporting layer 145 and the second supporting layer 155 may be made of a material different from the first sacrificial layer 140 and the second sacrificial layer 150. For example, the first supporting layer 145 and the second supporting layer 155 may be made of a material exhibiting an etching property different from the first sacrificial layer 140 and the second sacrificial layer 150. In some embodiments, the first supporting layer 145 and the second supporting layer 155 may be of a same material, such as silicon nitride, aluminum oxide, hafnium oxide, the like, or other suitable materials.

In some embodiments, the first sacrificial layer 140, first supporting layer 145, second sacrificial layer 150, and second supporting layer 155 may be deposited by, for example, ALD, CVD, PVD, or other suitable methods.

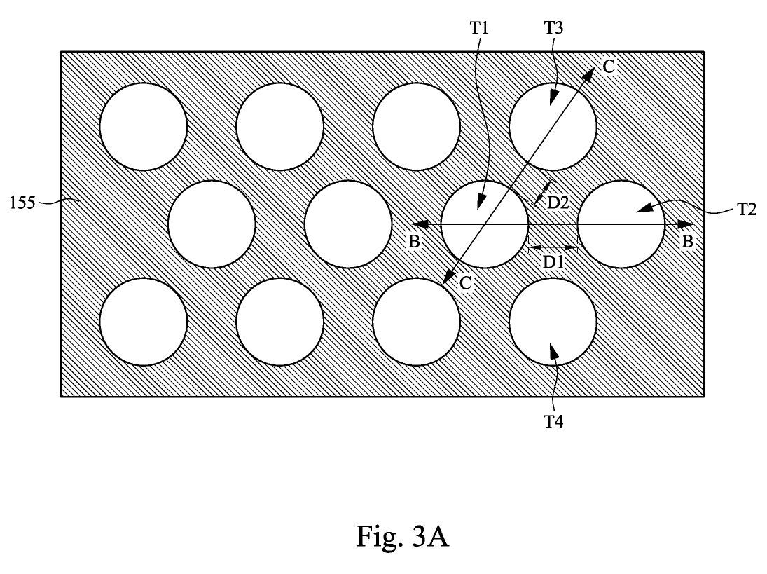

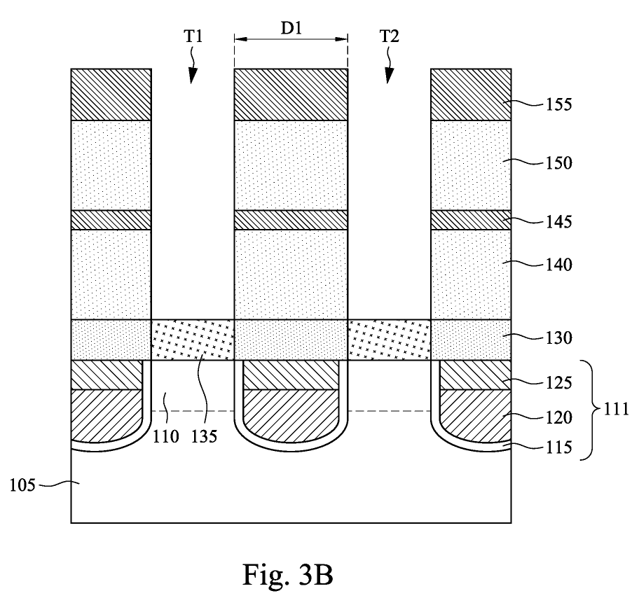

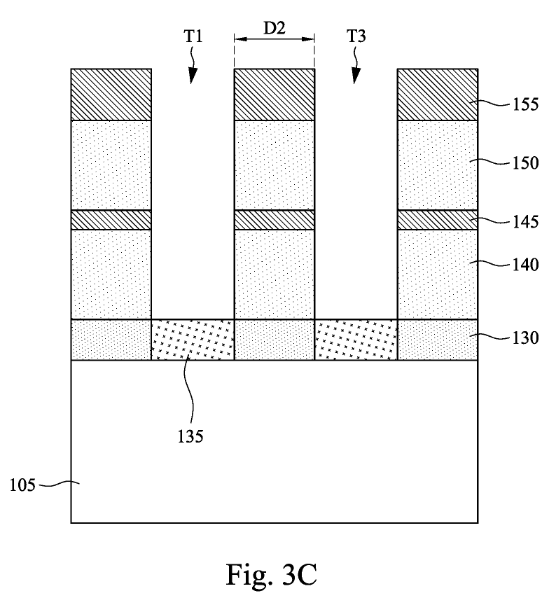

Reference is made to FIGS. 3A to 3C, in which FIG. 3A is a top view of a memory device, and FIGS. 3B and 3C are cross-sectional views along the lines B-B and C-C of FIG. 3A, respectively.

A plurality of trenches are formed through the stack of the first sacrificial layer 140, the first supporting layer 145, the second sacrificial layer 150, and the second supporting layer 155 using suitable photolithography process. In some embodiments, the trenches at least include trenches T1, T2, T3, and T4. In some embodiments, the trenches T1, T2, T3, and T4 may expose the respective contacts 135.

In some embodiments, the trenches may be formed by, for example, forming a patterned mask (e.g., photoresist) over the second supporting layer 155, in which the patterned mask may include openings that define the positions of the trenches (e.g., trenches T1 to T4). Afterwards, an etch process may be performed through the openings of the patterned mask to remove portions of the second supporting layer 155, the second sacrificial layer 150, the first supporting layer 145, and the first sacrificial layer 140, so as to form the trenches. In some embodiments, the etch process may be an anisotropic dry etch process.

It is noted that FIG. 3B is a cross-sectional view taken along the trenches T1 and T2, and FIG. 3C is a cross-sectional view taken along the trenches T1 and T3. The trenches T1 and T2 may include a shortest distance D1 therebetween, and the trenches T1 and T3 may include a shortest distance D2 therebetween. In some embodiment, the distance D1 is greater than the distance D2.

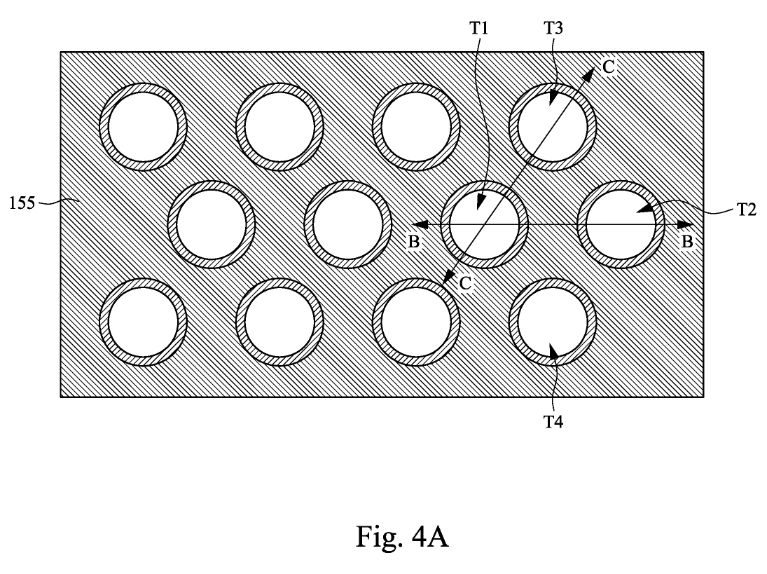

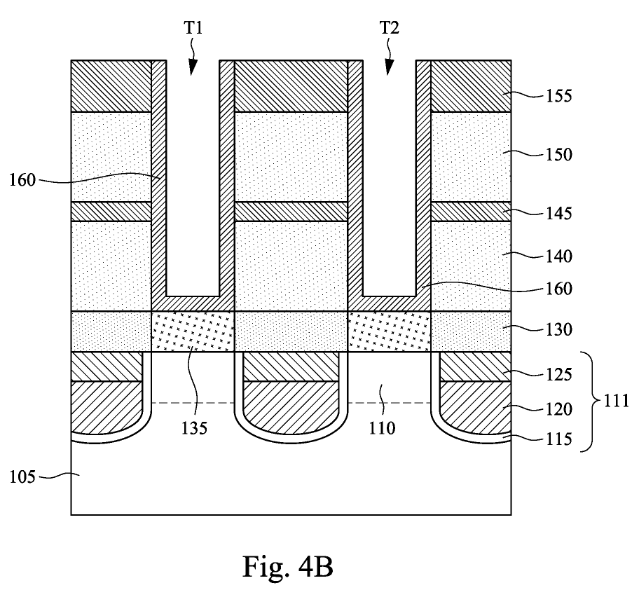

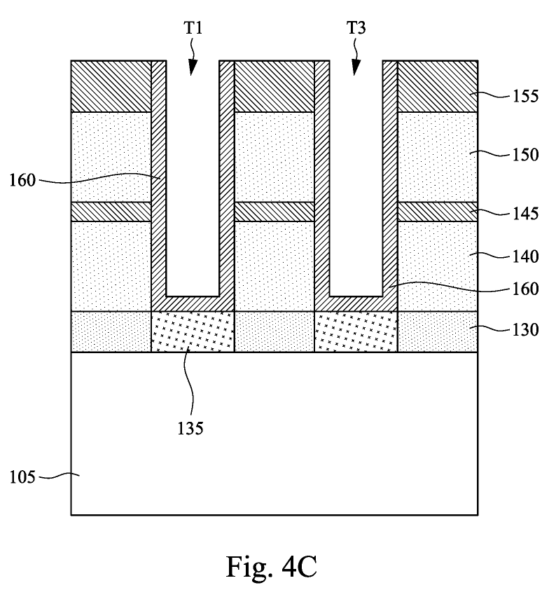

Reference is made to FIGS. 4A to 4C, in which FIG. 4A is a top view of a memory device, and FIGS. 4B and 4C are cross-sectional views along the lines B-B and C-C of FIG. 4A, respectively. After the formation of the trenches (e.g., trenches T1 to T4), bottom electrodes 160 are formed respectively into the trenches and in contact with the respective contacts 135. Accordingly, the bottom electrodes 160 may be electrically connected with the respective doped regions 110 in the substrate 105. In some embodiments, the bottom electrodes 160 may include a metallic material, such as titanium nitride (TiN) or ruthenium (Ru).

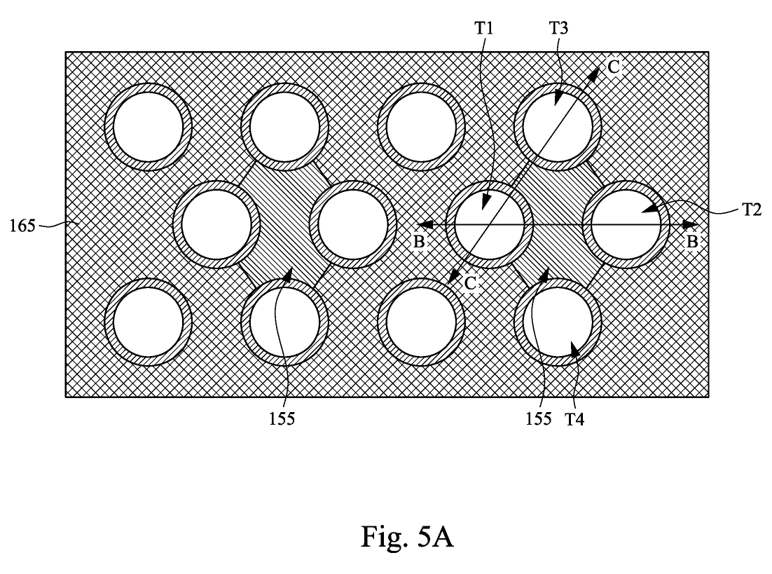

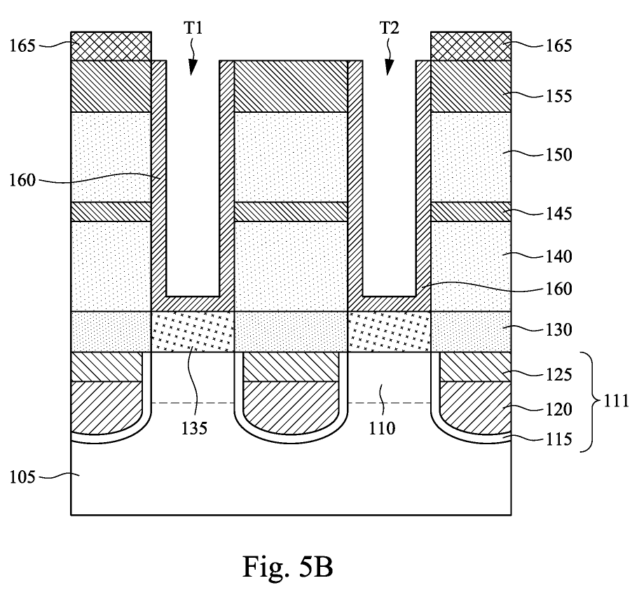

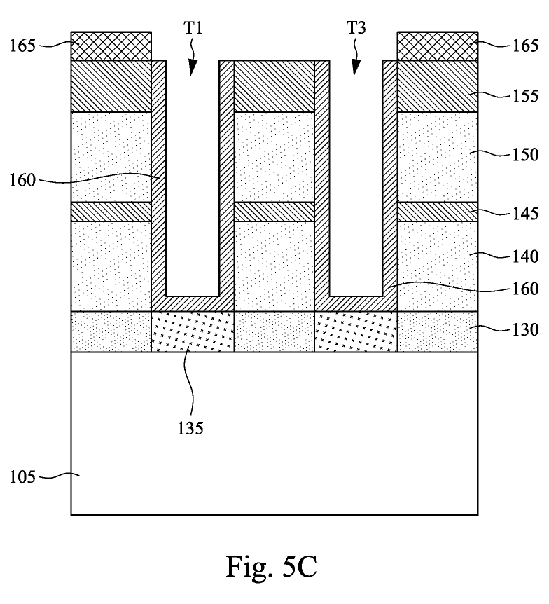

Reference is made to FIGS. 5A to 5C, in which FIG. 5A is a top view of a memory device, and FIGS. 5B and 5C are cross-sectional views along the lines B-B and C-C of FIG. 5A, respectively. A patterned mask 165 is formed over the stack of the first sacrificial layer 140, the first supporting layer 145, the second sacrificial layer 150, and the second supporting layer 155. In some embodiments, the patterned mask 165 may include at least one opening exposing portions of the second supporting layer 155. For example, as shown in the top view of FIG. 5A, at least an opening of the patterned mask 165 exposes a region of the second supporting layer 155 that is enclosed by the trenches T1, T2, T3, and T4.

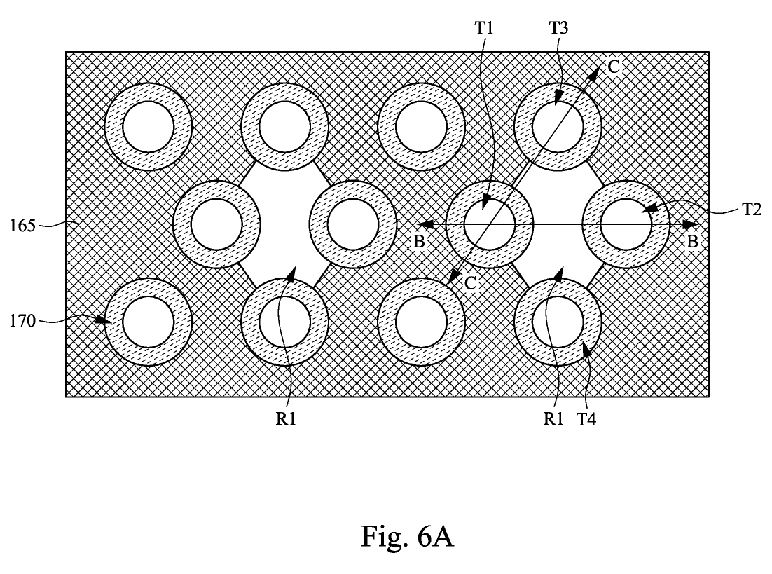

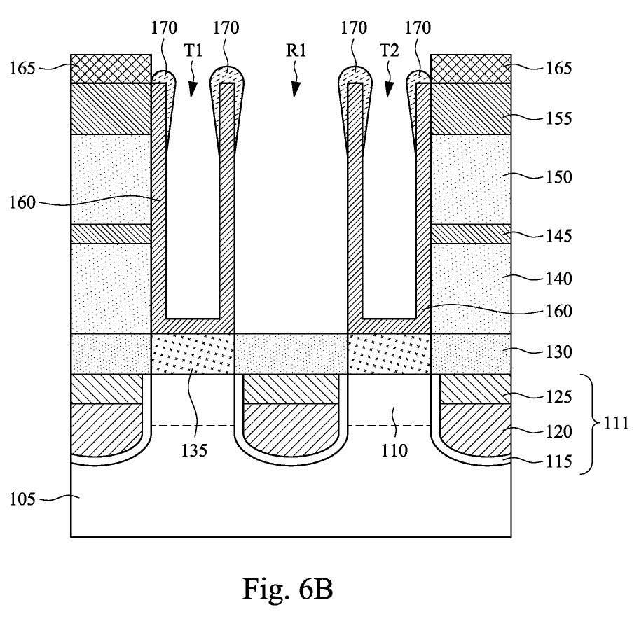

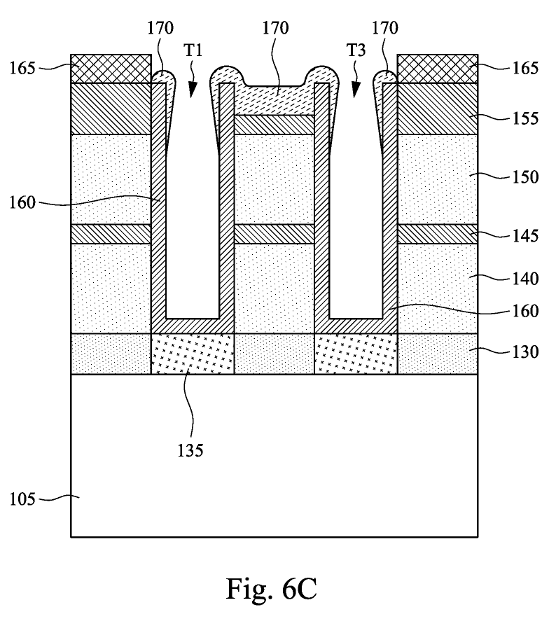

Reference is made to FIGS. 6A to 6C, in which FIG. 6A is a top view of a memory device, and FIGS. 6B and 6C are cross-sectional views along the lines B-B and C-C of FIG. 6A, respectively. After the formation of the patterned mask 165, an etch process is performed to remove portions of the first sacrificial layer 140, the first supporting layer 145, the second sacrificial layer 150, and the second supporting layer 155 through the openings of the patterned mask 165. During performing the etch process, polymers 170 may also be formed as byproducts of the etch process. Due to various chemical reactions, the polymers 170 are continuously deposited over the substrate 105, while the etch process continuously takes place as well. As a result, etching the stack of the first sacrificial layer 140, the first supporting layer 145, the second sacrificial layer 150, and the second supporting layer 155 and the formation of the polymers 170 occur substantially simultaneously and in a continuous manner. In some embodiments, the polymers 170 may be formed covering the exposed surfaces of the bottom electrodes 160. In some embodiments, the polymers 170 may wrap around the top ends of the bottom electrodes 160.

As shown in the cross-sectional view of FIG. 6B, the etch process may remove portions of the first sacrificial layer 140, the first supporting layer 145, the second sacrificial layer 150, and the second supporting layer 155 that are laterally between the trenches T1 and T2, so as to form a recess R1 between the trenches T1 and T2.

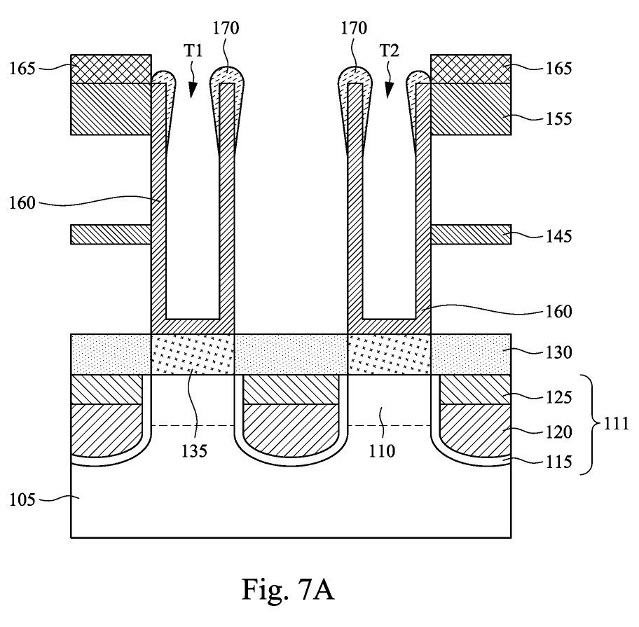

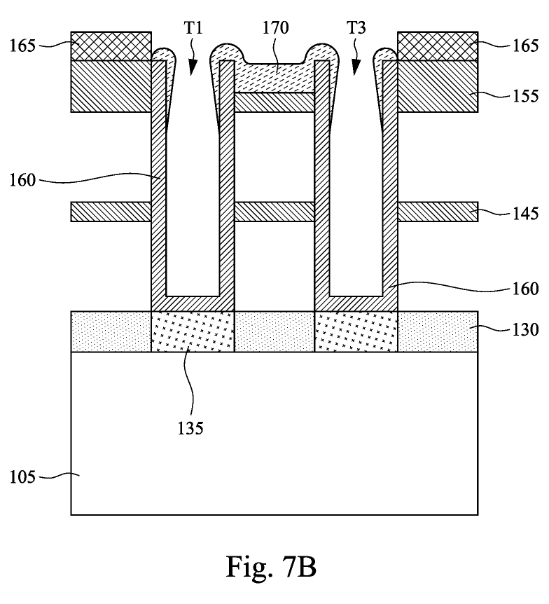

On the other hand, as shown in the cross-sectional view of FIG. 6C, during performing the etch process, the etch process may first remove a portion of the second supporting layer 155. However, because the short distance between the trenches T1 and T3, portions of the polymers 170 may fill the gap between the trenches T1 and T3, and may merge together over the etched second supporting layer 155. As a result, in FIG. 6C, the merged poly polymers 170 may act as a protective layer to prevent the portions of the first sacrificial layer 140, the first supporting layer 145, the second sacrificial layer 150, and the second supporting layer 155 laterally between the trenches T1 and T3 from being etched. Accordingly, once the etch process is complete, the portions of the first sacrificial layer 140, the first supporting layer 145, the second sacrificial layer 150, and the second supporting layer 155 laterally between the trenches T1 and T3 may remain, with the second supporting layer 155 being slightly etched. In some embodiments, the thickness of the portion of the second supporting layer 155 between the trenches T1 and T3 is reduced during the etch process. In some embodiments, as shown in FIG. 7B, the surface of the second supporting layer 155 between the trenches T1 and T3 is lower than the top ends of the bottom electrodes 160 after performing the etch process.

Referring back to the top view of FIG. 6A, it is noted that the polymers 170 may also merge together and fill the gap between the trenches T1 and T4, the gap between the trenches T2 and T3, and the gap between the trenches T2 and T4, respectively. In some embodiments, the polymers 170 may merge at a small gap between the trenches (e.g., gap between trenches T1 and T3, trenches T1 and T4, trenches T2 and T3, or trenches T2 and T4), the merged polymers 170 are formed in a self-align manner, and the boundary of the openings of the patterned mask 165 can be well defined, which in turn will improve the etching performance. On the other hand, the polymers 170 may also act as a protective layer for top ends of the bottom electrodes 160.

In some embodiments, the etch process is an anisotropic dry etch, such as a plasma dry etch. The etchant gases used during the dry etch may include CF₄, CHF₃, CH₂F₂, CH₃F, SF₆, NF₃, the like, or combinations thereof. The carrier gas used during the dry etch may include, H₂, N₂, Ar, the like, or combinations thereof. In some embodiments, the polymers 170 may include CₓH_{y}F_{z}.

Reference is made to FIGS. 7A and 7B, in which FIGS. 7A and 7B follow the cross-sectional views of FIGS. 6B and 6C, respectively. Another etch process may be performed to remove the first sacrificial layer 140 and the second sacrificial layer 150. In some embodiments, the etch process may be an isotropic wet etch process, so as to remove entire first sacrificial layer 140 and the second sacrificial layer 150 through the recesses R1 within the stack of the first sacrificial layer 140, the first supporting layer 145, the second sacrificial layer 150, and the second supporting layer 155. As a result, the first supporting layer 145 and the second supporting layer 155 may suspend over the substrate 105. In some embodiments, the etch process may include a higher etch rate to the first sacrificial layer 140 and the second sacrificial layer 150 than to the first supporting layer 145 and the second supporting layer 155.

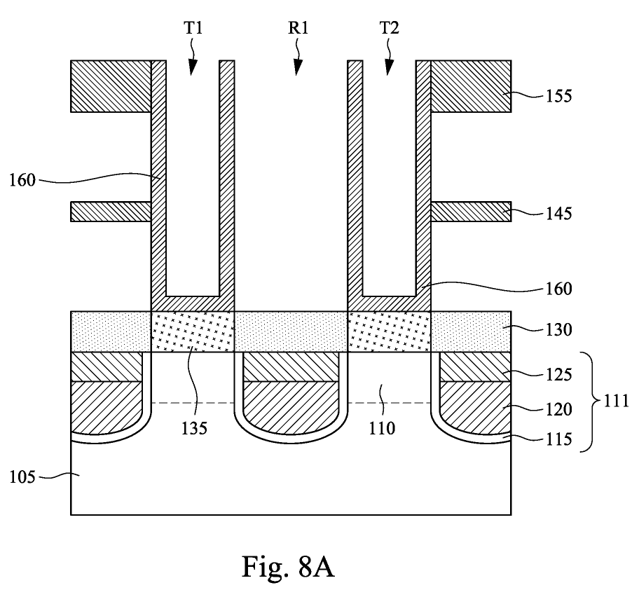

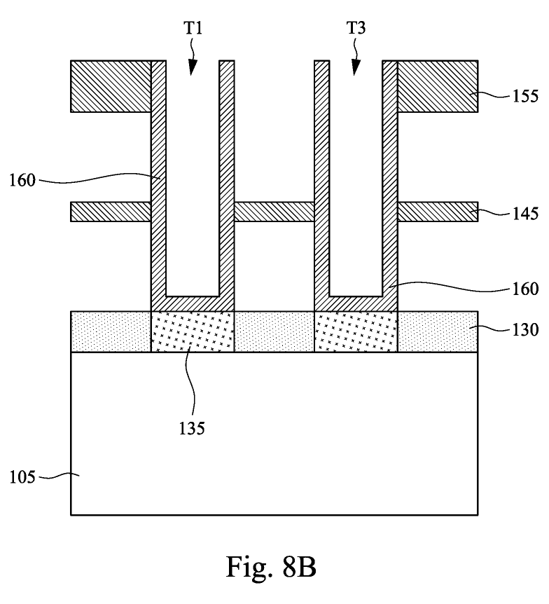

Reference is made to FIGS. 8A and 8B, in which FIGS. 8A and 8B follow the cross-sectional views of FIGS. 7A and 7B, respectively. The patterned mask 165 is removed. In some embodiments where the patterned mask 165 is photoresist, the patterned mask 165 may be removed using an ashing process or a striping process. Afterwards, a cleaning process may be performed to remove the polymers 170, so as to expose the top ends of the bottom electrodes 160. Because the polymers 170 may protect the bottom electrodes 160 during the previous etch processes, there is no loss or negligible loss for the bottom electrodes 160, and thus the device performance may be improved.

As shown in the cross-sectional view of FIG. 8B, during the cleaning process, the portion of the second supporting layer 155 between the trenches T1 and T3 may also be removed. As mentioned above, such portion may be consumed during the previous etch processes, and thus remaining material of the portion of the second supporting layer 155 may be removed together during the cleaning process.

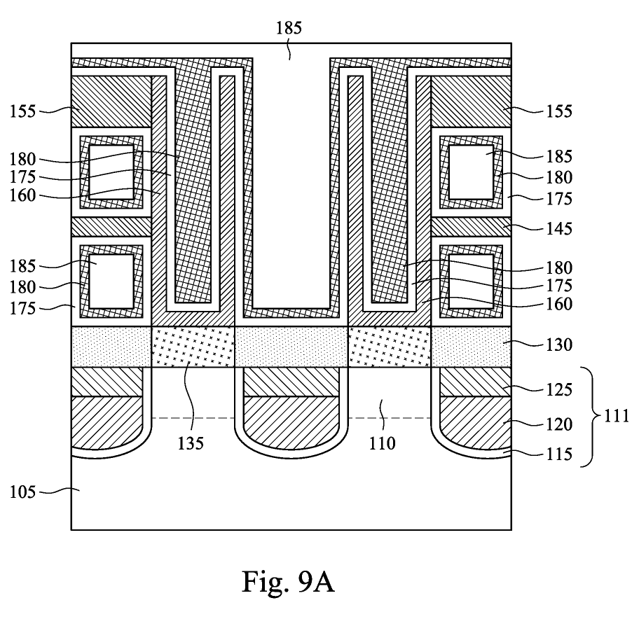

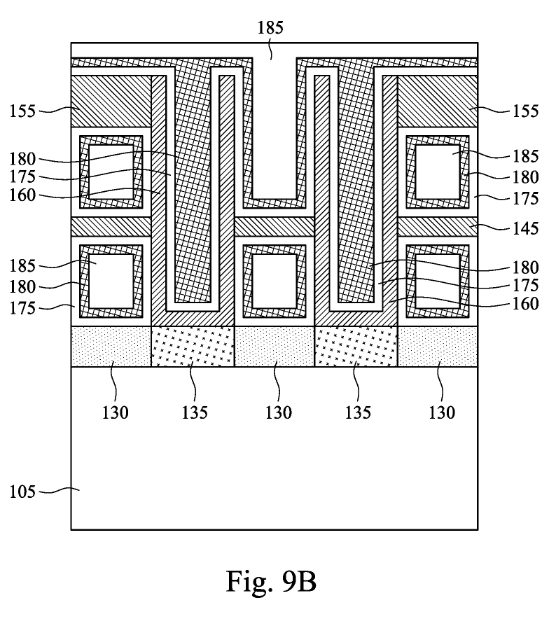

Reference is made to FIGS. 9A and 9B, in which FIGS. 9A and 9B follow the cross-sectional views of FIGS. 8A and 8B, respectively. Capacitor dielectric layers 175 are formed filling the trenches (e.g., the trenches T1 to T4) and the recesses R1 and extending along the surfaces of the bottom electrodes 160 and along the surfaces of the second supporting layer 155, the first supporting layer 145, and the dielectric layer 130. In some embodiments, the capacitor dielectric layers 175 may include tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), a dielectric material having a dielectric constant that is higher than that of silicon dioxide (SiO₂), or a dielectric material having a dielectric constant of about 4.0 or greater. In some embodiments, each of the capacitor dielectric layers 175 may be formed of a single layer or may be formed of stacked layers. In some embodiments, the capacitor dielectric layers 175 may be disposed by, for example, ALD, CVD, PVD, or other suitable methods.

Afterwards, top electrodes 180 are formed filling the trenches (e.g., the trenches T1 to T4) and the recesses R1, and over the capacitor dielectric layers 175. In some embodiments, the bottom electrodes 160 may include a metallic material, such as titanium nitride (TiN) or ruthenium (Ru). In some embodiments, the top electrodes 180 may be disposed by, for example, ALD, CVD, PVD, RPCVD, PECVD, LPCVD, coating, or other suitable methods.

An insulating layer 185 is formed over the top electrodes 180 and filling the remaining spaces in the structure shown in FIGS. 8A and 8B. In some embodiments, the insulating layer 185 may include, for example, borophosphosilicate glass (BPSG), tetraethyl orthosilicate (TEOS), phosphorus doped tetraethyl orthosilicate (PTEOS), epoxy-based material (e.g., FR4), resin-based material (e.g., Bismaleimide-Triazine (BT)), Polypropylene (PP), molding compound or other suitable materials.

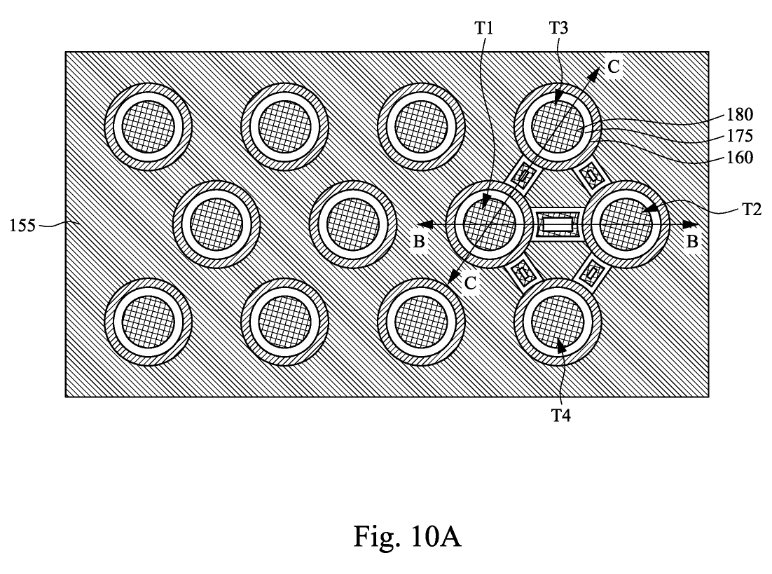

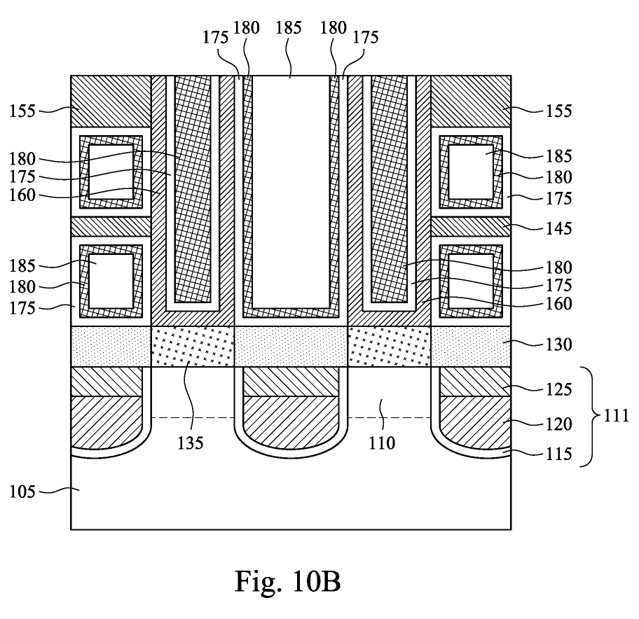

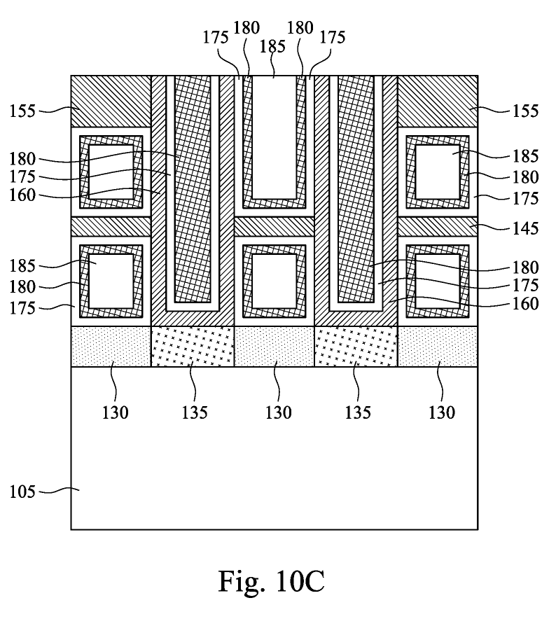

Reference is made to FIGS. 10A to 10C, in which FIG. 10A is a top view of a memory device, and FIGS. 10B and 10C are cross-sectional views along the lines B-B and C-C of FIG. 10A, respectively. A planarization process is performed on the structure shown in FIGS. 9A and 9B until the second supporting layer 155 is exposed. In some embodiments, the bottom electrode 160, the capacitor dielectric layer 175, and the top electrode 180 within each of the trenches may collectively serve as a capacitor 100C of the memory device 100 as discussed in FIG. 1. In some embodiments, the planarization process may be Chemical Mechanical Polishing (CMP) process.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for forming a memory device, comprising:
forming a stack comprising a first sacrificial layer, a first supporting layer, a second sacrificial layer, and a second supporting layer over a substrate;
forming a first trench and a second trench in the stack;
forming bottom electrodes in the first trench and the second trench, respectively;
forming a patterned mask over the stack, wherein the patterned mask has an opening exposing the stack;
performing an etch process to the stack through the opening of the patterned mask, wherein the etch process etches through a first portion of the stack to form a recess, while a second portion of the stack laterally between the first trench and the second trench is protected by a polymer generated during performing the etch process;
removing the first sacrificial layer and the second sacrificial layer from the stack through the recess;
forming capacitor dielectric layers over the bottom electrodes, respectively; and
forming top electrodes over the capacitor dielectric layers, respectively.

2. The method ofclaim 1, wherein the polymer is formed on surfaces of the bottom electrodes during performing the etching process.

3. The method ofclaim 1,wherein a portion of the second supporting layer of the second portion of the stack is etched during the etch process.

4. The method of claim 1, further comprising:
removing the patterned mask after removing the first sacrificial layer and the second sacrificial layer; and
removing the polymer.

5. The method of claim 4, wherein removing the polymer is performed after removing the patterned mask.

6. The method of claim 1, the capacitor dielectric layers are formed over the second supporting layer and in the recess.

7. The method of claim 1, further comprising forming an insulating layer over the top electrodes and filling the recess.

8. The method of claim 1, further comprising forming a transistor in the substrate, wherein one of the bottom electrodes is electrically connected to the transistor.

9. The method of claim 1, wherein the polymer extends from a first portion of the bottom electrodes within the first trench to a second portion of the bottom electrodes within the second trench.

10. The method of claim 1, wherein forming the first trench and the second trench in the stack further comprises forming a third trench in the stack, a shortest distance between the first trench and the second trench is less than a shortest distance between the first trench and the third trench, and wherein the recess is formed laterally between the first trench and the third trench.

11. A method for forming a memory device, comprising: forming a stack comprising a first sacrificial layer, a first supporting layer, a second sacrificial layer, and a second supporting layer over a substrate;
forming a first trench, a second trench, and a third trench in the stack, wherein a distance between the first trench and the second trench is less than a distance between the first trench and the third trench;
forming bottom electrodes in the first, second, and third trenches, respectively;
forming a patterned mask over the stack, wherein the patterned mask has an opening exposing the stack;
performing an etch process to the stack through the opening of the patterned mask to form a recess in the stack, wherein after the etch process is complete, a first portion of the second supporting layer laterally between the first trench and the second trench remains, while a second portion of the second supporting layer
laterally between the first trench and the third trench is removed;
removing the first sacrificial layer and the second sacrificial layer from the stack through the recess;
forming capacitor dielectric layers over the bottom electrodes, respectively; and
forming top electrodes over the capacitor dielectric layers, respectively.

12. The method of claim 11, wherein performing the etch process further comprises forming a polymer over the first portion of the second supporting layer.

13. The method of claim 12, wherein the polymer further extend to portions of the bottom electrodes within the first trench and the second trench.

14. The method of claim 13, wherein the polymer wraps top ends of the bottom electrodes within the first trench and the second trench.

15. The method of claim 12, further comprising:
removing the patterned mask after removing the first sacrificial layer and the second sacrificial layer; and
removing the polymer after removing the patterned mask.

16. The method ofclaim 15, wherein removing the polymer further comprises removing the first portion of the second supporting layer.

17. The method of claim 11, wherein after the etch process is complete, a top surface of the first portion of the second supporting layer is lower than top ends of the bottom electrodes.

18. The method of claim 11, wherein the etch process is performed such that a thickness of the first portion of the second supporting layer is reduced.

19. The method of claim 11, further comprising forming a transistor in the substrate, wherein one of the bottom electrodes is electrically connected to a source/drain region of the transistor.

20. The method of claim 11, wherein the etch process is performed such that portions of the first sacrificial layer, the first supporting layer, and the second sacrificial layer under the second portion of the second supporting layer are removed.
